(19) United States
(12) Patent Application Publication
(10) Pub. No.: US 2024/0192367 A1
(43) Pub. Date: Jun. 13, 2024

(54) OBJECT OR SURFACE NOISE-LEVEL DETECTION USING RADARS AND/OR LIDARS

(71) Applicant: General Noise Ltd, Eastbourne (GB)

(72) Inventors: Robert G. W. Brown, Eastbourne (GB); Jason E. Dunne, Eastbourne (GB)

(21) Appl. No.: 17/906,723

(22) PCT Filed: Aug. 31, 2022
(86) PCT No.: PCT/IB22/00560

§ 371 Date: Sep. 19, 2022

Related U.S. Application Data
(60) Provisional application No. 63/238,987, filed on Aug. 31, 2021.

(51) Int. Cl. G01S 17/58; G01R 23/17; G01S 7/41; G01S 7/48; G01S 13/58; G01S 13/86; G01S 17/10; G01S 17/86; H04R 1/32

(52) U.S. Cl. CPC G01S 17/58; G01R 23/17; G01S 7/415; G01S 7/4802; G01S 13/581; G01S 13/867; G01S 17/10; G01S 17/86; H04R 1/326

(57) ABSTRACT

The present invention is directed to a system for measuring noise and velocity of a single object or surface in a soundscape of multiple noise-emitting objects or surfaces. The present invention features a system comprising a heterodyne signal system comprising a signal emitter, a signal receiver, and a signal processing component capable of directing an original signal to the object or surface, accepting a return signal Doppler shifted and mixed with the original signal, and removing the original signal, resulting in an output signal. The system may further comprise an acoustic spectrum analyzer capable of calculating a radiation-factor from the output signal, calculating a mean-squared velocity value by calculating a variance of a spectral shape of the output signal, calculating a noise-sound-power value from the mean-squared velocity value and the radiation-factor, and converting the noise-sound-power value into an acoustic decibel value.

### CROSS-REFERENCES TO RELATED APPLICATIONS

This application claims benefit of U.S. Provisional Application No. 63/238,987 filed Aug. 31, 2021, the specification of which is incorporated herein in its entirety by reference.

### FIELD OF THE INVENTION

The present invention is directed to a system for measuring noise and velocity of a single object or surface in a soundscape of multiple noise-emitting objects or surfaces, such as a highway or airport noise contour.

### BACKGROUND OF THE INVENTION

Noise can be both irritating and harmful. Over 60% of the UK population report living in homes currently blighted by exhaust noise—blighted not by tyre roar or wind noise, but specifically by vehicles accelerating and revving (DEFRA 2012 noise survey). Per the WHO's noise guidelines: “ . . . more than half of all European Union citizens live in acoustically uncomfortable zones. At night, >30% are exposed to sound levels exceeding 55 dB(A)”.

Noise can be a daily torture to individuals with noise-sensitive conditions, some of whom cannot speak for themselves (e.g. autism, schizophrenia). They often suffer behind closed doors and their sensitivity to noise is rarely even discussed by policymakers. More generally, traffic noise has been shown to impair everything from birdsong to ischaemic health to childhood cognitive development.

Consequently, every national government regulates vehicle and aviation exhaust noise to some degree. Traditionally, “noise law” enforcement technology has been based on audio microphones, or simply the ears of an enforcing official. Both methods are error-prone and require manual labor. Conversely, the automated enforcement of noise law has barely begun. Only a few jurisdictions across the world have implemented trials of automated noise “cameras”, but the global take-up of such systems seems inevitable, as was the case with the automated enforcement of speeding. Cash-pressed authorities are likely to financially benefit from automated noise enforcement systems.

Road noise is a global problem, one that is getting worse thanks to the ever-increasing availability of loud vehicles. It'll be a long time before electric vehicles make a difference. Meanwhile, the SARS-COV-2 global lockdown showed what a more peaceful and tranquil world might sound like.

Newspaper coverage from around the world shows that the Police and Transport Authority enforcement of noise has largely failed. These enforcement efforts will never fully succeed for as long as audio microphone equipment is used. Microphone-based “noise cameras” are currently being trialed by UK police, as well as the Department of Transport and several local Councils. It is known that those trials are not going well, mainly because detector microphones are incapable of determining the precise location and direction of the origin of the sound, i.e. if more than one vehicle is at the scene, it's hard to automatically isolate the precise vehicle(s) emitting the measured sound. Such designs of noise cameras work best when there is just one car on the road. That is a severe operating limit for noise cameras based around an audio microphone, rather than laser-vibrometry or radar-guns.

Additionally, microphone-based noise camera evidence is hard to interpret and is easily challenged in court. In some designs of noise cameras, such as those by 24Acoustic Ltd, traffic officers are given a waveform graph of the entire soundscape, when what's really needed is a picture/video overlay which helps to establish that the noise truly did come from the accused vehicle and not another soundsource alongside it. Also, industrial-grade audio microphones must be calibrated regularly, meaning an ongoing expense and yet more manual labor.

Police (usually near-infra-red) laser-radars—and (often ˜34.7 GHZ) radar-guns—are both widely used to determine vehicle velocity. Two techniques are used to estimate velocity: (1) sending a stream of accurately-repetitive narrow laser-pulses at the target and measuring the average-change in round-trip time as the vehicle moves, or (2) emitting a pulse of radar-waves and measuring its reflected Doppler-frequency-shift to determine vehicle velocity. The Doppler-frequency-shift system layout is typically as shown in FIG. 4 (for Radar, just replace ‘Laser’ with ‘Radar’), and is commonly known as a heterodyne-system.

A typical NHTSA approved lidar (laser radar) device emits 30 ns pulses of laser light with wavelength 905 nm and 50 milliwatts of power with 3 milliradian beam divergence. The power is sufficiently low to ensure no ocular damage occurs. At 905 nm wavelengths, IEC 60825-1 Edition 2.0 allows a maximum energy per pulse of 0.5 micro-Joules. Light travels approximately 30 cm per nanosecond (ns) so each pulse has a length of about nine meters. At a target distance of 300 meters the light pulses take 2,000 ns to complete the round trip. The time interval between pulses is no less than one million ns, providing time to make a distance estimation from each pulse. Up to several hundred pulse readings are taken over a period less than half a second and used to estimate the change in distance over time, thereby estimating vehicle speed. Returning light is filtered to exclude light not in the wavelength range 899 nm to 909 nm. An internal proprietary algorithm rejects inaccurate readings; detection avoidance methods usually attempt to overload the filter and persuade the error rejection algorithm to incorrectly reject a reading. For example, if the roundtrip time-change (directly-proportional to distance-traveled) between a pulse emitted at time-zero, and a pulse emitted at time-1-second is 100 feet, then the vehicle velocity is: (100×3600)/5280=68 mph. [N.B. 3600 seconds per hour; 5280 feet per mile].

Current designs of cameras are mounted on fixed position lamp-posts, with the planning difficulties that implies, and concerns over government surveillance by microphones positioned at street level. No product currently exists for a fully mobile, remote-sensing, hand-held noise detector, unlike the hand-held speed cameras used by police. The present application shows that simple additional signal-processing calculations on the very same signals that are used in standard police laser-radars and radar-guns can deliver the noise emission level from a specifically identified and photographed vehicle by the officer collecting data for well-known and successful law enforcement proceedings. A noise camera based on radar/lidar may also have application in expansive or hazardous environments, such as maritime and aviation, measuring noise at significant distance e.g. long after an aeroplane has left an airport's perimeter. A radar/lidar noise camera will also enjoy lower construction and maintenance costs compared to a noise camera based on a class 1 microphone and anemometer. Finally, a radar-based device can operate from inside a police car's cabin or on a police motorbike, when a microphone-based camera could not.

### BRIEF SUMMARY OF THE INVENTION

It is an objective of the present invention to provide systems and methods that allow for measuring noise and velocity of a single object or surface in a soundscape of multiple noise-emitting objects or surfaces, such as a highway or flight path, as specified in the independent claims. Embodiments of the invention are given in the dependent claims. Embodiments of the present invention can be freely combined with each other if they are not mutually exclusive.

The present invention features a method for measuring noise of a single object or surface in a soundscape of multiple noise-emitting objects or surfaces. In some embodiments, the method may comprise providing a heterodyne signal system. The heterodyne signal system may comprise a signal emitter, a signal receiver, and a signal processing component. The method may further comprise directing, by the signal emitter, an original signal to the single object or surface and accepting, by the signal receiver, a return signal. The return signal may be Doppler shifted and mixed with the original signal. The method may further comprise removing, by the signal processing component, the original signal. This may result in an output signal comprising changes to oscillation carrier frequency. The method may further comprise calculating, by the acoustic spectrum analyzer, a radiation-factor from the output signal and calculating, by an acoustic spectrum analyzer communicatively coupled to the heterodyne signal system (200), a mean-squared velocity value from the output signal. Calculating the mean-squared velocity value may comprise calculating a variance of a spectral shape of the output signal. The method may further comprise calculating, by the acoustic spectrum analyzer, a noise-sound-power value from the mean-squared velocity value and the radiation-factor and converting, by the acoustic spectrum analyzer, the noise-sound-power value into an acoustic decibel value.

The present invention features a system for measuring noise of a single object or surface in a soundscape of multiple noise-emitting objects or surfaces. In some embodiments, the system may comprise a heterodyne signal system. The heterodyne signal system may comprise a signal emitter, a signal receiver, and a signal processing component. The signal processing component may be capable of directing an original signal to the single object or surface, accepting a return signal, such that the return signal may be Doppler shifted and mixed with the original signal, and removing the original signal, resulting in an output signal may comprise changes to oscillation carrier frequency. The system may further comprise an acoustic spectrum analyzer communicatively coupled to the heterodyne signal system (200). The acoustic spectrum analyzer may be capable of accepting the output signal from the heterodyne signal system, calculating a radiation-factor from the output signal, calculating a mean-squared velocity value from the output signal, wherein calculating the mean-squared velocity value may comprise calculating a variance of a spectral shape of the output signal, calculating a noise-sound-power value from the mean-squared velocity value and the radiation-factor, and converting the noise-sound-power value into an acoustic decibel value.

In addition to BOTH the pulsed-laser and the (pulsed) radar-heterodyne signal-processing schemes used for velocity determinations (as just described), the present invention introduces the spectrum-analysis of the very same pulsed velocity-signals—to determine the acoustic spectrum and its intensity emitted by the target object or surface—precisely at the same moment in time and from the exact same signal from which the velocity is determined. Thus the police Lidar or Radar (or a cell-phone or mobile-phone fitted with LIDAR) can have the picture of the object or surface and its velocity as usual, but additionally displayed can be that specific object or surface's noise-loudness, e.g., in dBA.

The present invention is directed to measuring and specifically identifying an object's noise-emission level greater than a target or trigger dB-level, or some legal limit—by detection at a sufficient quality and integrity level—for successful legal prosecution. The present invention may modify existing police laser-radars or radar guns (or use a lidar-equipped cell-phone)—to measure sound-level and its spectrum at the object or surface (using the exact same signal used for instantaneous velocity-determination)—at the hand-held camera or fixed-position device.

Identification of the precise target object or surface may be accomplished using the coaxially/adjacently bore-sighted laser/radar-beam and photographic camera employed in standard police LIDAR/RADAR equipment—or using a LIDAR-cell-phone. In some embodiments, a corroborating sound-level and spectrum might be achieved by detection via a directional microphone attached to the observer's-location police lidar/radar. In such embodiments, the LIDAR/RADAR may be correlated with the directional microphone's separately-determined acoustic spectra—to be, for example, over 95% certain of the sound-source and the loudness-level.

One of the unique and inventive technical features of the present invention is the calculation of a mean-squared velocity value from a signal by calculating the signal's variance. Without wishing to limit the invention to any theory or mechanism, it is believed that the technical feature of the present invention advantageously provides for the noise and velocity measurement of a single noise-emitting object or surface in an environment of multiple sound-emitting objects or surfaces. None of the presently known prior references or work has the unique inventive technical feature of the present invention. Furthermore, the prior references teach away from the present invention. For example, prior systems measure a single frequency signal to measure a noise-frequency value. The calculations of the present invention advantageously allow for a single object or surface's noise-frequency to be identified from multiple object or surface's noise frequencies, which has never been possible in prior single-frequency systems.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### BRIEF DESCRIPTION OF THE SEVERAL VIEWS OF THE DRAWING(S)

The features and advantages of the present invention will become apparent from a consideration of the following detailed description presented in connection with the accompanying drawings in which:

FIG. 1 shows a flow chart of a method for detecting a noise-level of a single object or surface in a soundscape of multiple noise-emitting objects or surfaces.

FIG. 2 shows a schematic of a system for detecting a noise-level of a single object or surface in a soundscape of multiple noise-emitting objects or surfaces.

FIG. 3A shows an existing police laser-radar in operation. The laser-beam and imaging-camera can be either co-axially bore-sighted or used through adjacent-lenses having overlapping fields-of-view.

FIG. 3B shows an existing fully-automated installation for detecting noise levels of objects or surfaces in a soundscape of multiple noise-emitting objects or surfaces.

FIG. 4 shows an example (laser or radar) heterodyne-system geometry—as used inside standard radar systems.

FIG. 5 shows a frequency-spectra of (a) (narrow peak) a single object or surface velocity-component—and (b) (broad) noise-sound across audio-frequencies (and beyond), as possibly measured. The horizontal axis represents frequency (=velocity), the vertical axis represents amplitude or intensity of that frequency (velocity). Frequency and velocity are interchangeable terms; one is directly proportional to the other. Trace (c) represents the correct sound-spectrum—following Doppler-shift correction by subtracting, if the object or surface is approaching the present invention, or adding, if the object or surface is moving further from the present invention, the object-component (a) from the shifted sound-components (b).

FIGS. 6A-6B show a possible correlation of simulated microphone acoustic (AAAX) and radar/laser vibrometer (BBBY) spectra. The x-axis is frequency, the y-axis is intensity. These spectra are 97% correlated.

FIG. 7 shows human-weighted acoustic-power decibels, as in curve A, used to convert power decibels into dBA—that relate to the human response to sound.

FIG. 8 shows a system schematic for the present invention. Pulses are emitted and received as usual from a laser or radar velocimeter. Optionally, a directional-microphone may be used to gather target object or surface sound level. The laser/radar detector (microphone also) output is fed directly to a spectrum analyser to determine the sound-spectrum frequency components. The spectrum is fed to a computer to calculate the dBA sound-noise level. That value is fed to the display of the target object or surface's velocity, whereupon it is displayed to the observer. Data may be stored and administratively actioned depending on the results exceeding some predefined target-values.

### DETAILED DESCRIPTION OF THE INVENTION

Following is a list of elements corresponding to a particular element referred to herein:
100 system
200 heterodyne signal system
210 signal emitter
220 signal receiver
230 signal processing component
300 acoustic spectrum analyzer

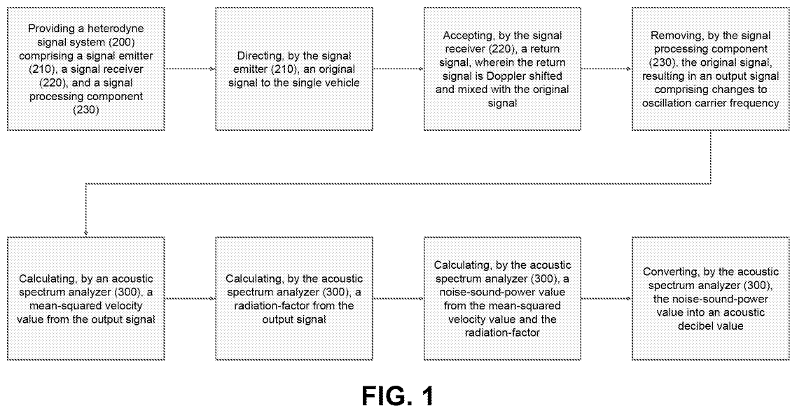

Referring now to FIG. 1, the present invention features a method for measuring noise of a single object or surface in a soundscape of multiple noise-emitting objects or surfaces. In some embodiments, the method may comprise providing a heterodyne signal system (200). The heterodyne signal system (200) may comprise a signal emitter (210), a signal receiver (220), and a signal processing component (230). The signal processing component (230) may comprise a processor capable of executing computer-readable instructions and a memory component comprising a plurality of computer-readable instructions. The method may further comprise directing, by the signal emitter (210), an original signal to the single object or surface and accepting, by the signal receiver (220), a return signal. The return signal may be Doppler shifted and mixed with the original signal. The method may further comprise removing, by the signal processing component (230), the original signal. This may result in an output signal comprising changes to oscillation carrier frequency. The method may further comprise calculating, by the acoustic spectrum analyzer (300), a radiation-factor from the output signal and calculating, by an acoustic spectrum analyzer (300), a mean-squared velocity value from the output signal. Calculating the mean-squared velocity value may comprise calculating a variance of a spectral shape of the output signal. The method may further comprise calculating, by the acoustic spectrum analyzer (300), a noise-sound-power value from the mean-squared velocity value and the radiation-factor and converting, by the acoustic spectrum analyzer (300), the noise-sound-power value into an acoustic decibel value.

In some embodiments, the heterodyne signal system (200) may comprise a LIDAR signal system. In other embodiments, the heterodyne signal system (200) may comprise a laser signal system or a RADAR signal system. This heterodyne signal system (200) may further comprise a laser/RADAR gun. In some embodiments, the heterodyne signal system (200) and the acoustic spectrum analyzer (300) may comprise a portable computing device (i.e. a mobile phone). In some embodiments, the method may further comprise providing a calibrated directional microphone placed on or near the heterodyne signal system (200) for cross-checking noise-intensity level and spectrum calculated by the acoustic spectrum analyzer (300). In some embodiments, the method may further comprise recording, by a camera, a photograph or video recording of the single object or surface. In some embodiments, the method may further comprise transmitting, by a communication component, the acoustic-decibel value and the photograph or video recording to a cloud server. The communication component may transfer data over a WiFi or BlueTooth connection. The data may be transmitted for the purpose of fines, court appearances, invitations to a noise test center, or to otherwise sanction, control or warn an entity with regard to noise output or laser/RADAR derived noise data.

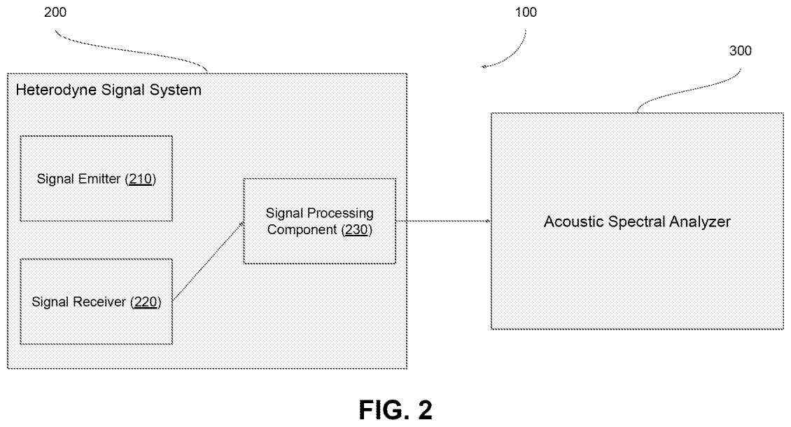

Referring now to FIG. 2, the present invention features a system (100) for measuring noise of a single object or surface in a soundscape of multiple noise-emitting objects or surfaces. In some embodiments, the system may comprise a heterodyne signal system (200). The heterodyne signal system may comprise a signal emitter (210), a signal receiver (220), and a signal processing component (230).

The signal processing component (230) may comprise a processor capable of executing computer-readable instructions and a memory component comprising a plurality of computer-readable instructions. The computer-readable instructions may comprise directing an original signal to the single object or surface, accepting a return signal, such that the return signal may be Doppler shifted and mixed with the original signal, and removing the original signal, resulting in an output signal may comprise changes to oscillation carrier frequency. The system (100) may further comprise an acoustic spectrum analyzer (300) capable of executing computer-readable instructions. The acoustic spectrum analyzer (300) may comprise a processor capable of executing computer-readable instructions and a memory component comprising a plurality of computer-readable instructions. The computer-readable instructions may comprise accepting the output signal from the heterodyne signal system (200), calculating a radiation-factor from the output signal, calculating a mean-squared velocity value from the output signal, wherein calculating the mean-squared velocity value may comprise calculating a variance of a spectral shape of the output signal, calculating a noise-sound-power value from the mean-squared velocity value and the radiation-factor, and converting the noise-sound-power value into an acoustic decibel value.

In some embodiments, the heterodyne signal system (200) may comprise a LIDAR signal system. In other embodiments, the heterodyne signal system (200) may comprise a laser signal system or a RADAR signal system. This heterodyne signal system (200) may further comprise a laser/RADAR gun. In some embodiments, the heterodyne signal system (200) and the acoustic spectrum analyzer (300) may comprise a portable computing device (i.e. a mobile phone). In some embodiments, the system (100) may further comprise a calibrated directional microphone placed on or near the heterodyne signal system (200) for cross-checking noise-intensity level and spectrum calculated by the acoustic spectrum analyzer (300). In some embodiments, the system (100) may further comprise a machine learning component for employing machine vision, artificial intelligence, or a combination thereof for calculation of sound-source dimensions. The machine learning component may comprise a processor capable of executing computer-readable instructions and a memory component comprising a plurality of computer-readable instructions. The machine learning component may be trained by a plurality of waveforms corresponding to a plurality of object types and sound emitters. This may allow the machine learning component to accept a waveform and identify the object type and/or the sound emitter based on a shape and size of the waveform. In some embodiments, the system (100) may further comprise a camera for recording a photograph or video recording of the single object or surface. In some embodiments, the system (100) may further comprise a communication component, the acoustic-decibel value and the photograph or video recording to a cloud server. The communication component may transfer data over a WiFi or BlueTooth connection. The data may be transmitted for the purpose of fines, court appearances, invitations to a noise test center, or to otherwise sanction, control or warn an entity with regard to noise output or laser/RADAR derived noise data. The system (100) of the present invention may be hand-held, tripod-mounted, lamp-post, tower, drone, bridge, or building mounted. The system (100) of the present invention may be retro-fittable to standard law enforcement LIDAR/RADAR velocimeters to upgrade them for acoustic sound/noise measurement capabilities.

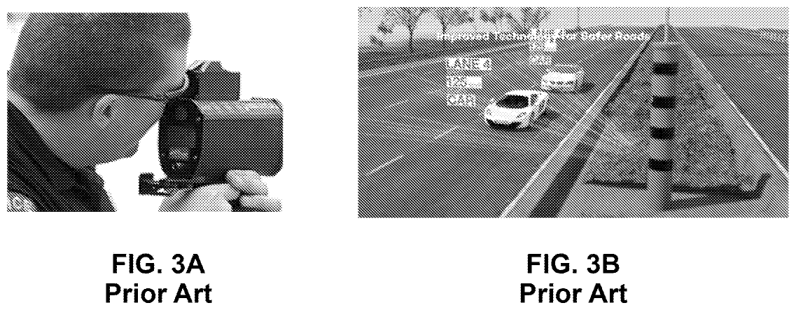

FIG. 3A shows an existing police laser-radar in operation. The laser-beam and imaging-camera are either co-axially bore-sighted, or operated through adjacent-lenses looking at overlapping fields of view. The police officer “points-and-shoots” the laser-radar (or radar-gun) at the object or surface being investigated, in order to determine its velocity. The repetitively-pulsed laser-beam is not just round-trip-modified by the velocity of the object or surface—it is also frequency-modulated by the vibrations of the object or surface from which it is being reflected. By using the typically 1-meter area being interrogated by the laser beam at the object or surface, the acoustic-emissions of that object or surface can be quantified inside the police laser-radar equipment, especially if the object or surface sound-emitter together with the registration/license-plate—are imaged together; similarly for a radar-gun. FIG. 3B shows broadly the same technology and process deployed in a fully-automated, fixed-position “tower installation”.

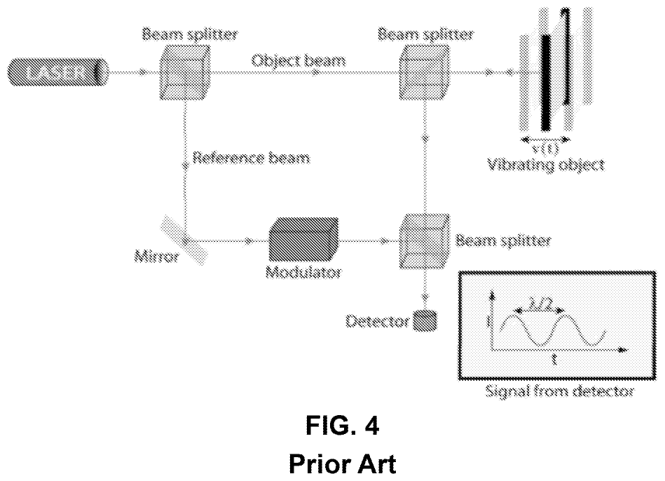

FIG. 4 shows schematically how a heterodyne-radar operates. A beam of radar (or laser), usually pulsed, (but could be a continuous)—proceeds through a beam-splitter that directs most of that beam through a second beam-splitter to the moving and vibrating target object or surface. The radar/light reflected by that object or surface is frequency-modulated by the well-known Doppler-shift, and passes back through that second beam-splitter—where it is now directed to meet-up with the small amount of light from the first beam-splitter sent to meet it in a beam-splitter adjacent to a detector. Mixing the two light beams together demodulates (eliminates) the raw radar/laser-frequency, leaving only the quasi-sinusoidal frequency-variations from the object or surface's acoustic spectrum as a well as its velocity to be further analyzed (see the sine-wave graph in FIG. 4). Normally only the average frequency-shift due to the object or surface velocity is estimated, but by further analyzing the frequency-spectrum, the sound-intensity at that observed and photographically recorded object or surface can be calculated. The velocity might be calculated from a single laser/radar pulse, but typically is the summation of signals from multiple pulses—to improve accuracy; similarly the noise-spectrum will be improved by such signal integration.

Sound intensity calculation proceeds as follows. The ISO/TR 7849 method is likely to be unaffected by object or surface motion—both if the observer is static—or happens also to be moving). The procedure of the present invention is devised as follows: measuring the frequency-spectrum and its average quantity using the radar/laser-vibrometer and correcting this frequency-spectrum for object or surface velocity-bias (well-known Doppler shift) prior to calculations. The procedure may further comprise calculating σ, the radiation-factor from the following equation (1):

$$10 log σ = - log [ 1 + 0.1 \frac{{c}^{2}}{{( fR )}^{2}} ] \qquad ( 1 )$$

where f is the measured dominant acoustic frequency in Hz, c is the velocity of sound in air, and R is the characteristic dimension being measured; 1-meter diameter is not uncommon in a police laser vibrometer, but a sub-dimension—for example, perhaps just the exhaust-size—could easily be defined and machine-vision-calculated from the image of the object or surface taken by the police camera, if advantageous.

From the calculation of σ, proceed to the calculation of noise-sound-power, Wₜₒₜ, using the following equation (2):

Wₜₒₜ=σρcSv² (2)

where ρ is the mean air density, S is the observed surface-area—and “v-squared bar” is the mean-squared value of the normal velocity averaged over the observation area (typically 1-meter diameter, as noted above). This v-parameter is calculated for a moving object or surface from the distribution of velocities in the sound spectrum plus/minus the object or surface's average directional velocity (Doppler-shift correction), so the distribution is now centered about the value zero before the mean-square displacement is calculated from the root-mean-square (rms) calculation widely used in statistics. The velocity-bias of the moving object or surface is thus correctly eliminated before calculations of the rms and variance proceed.

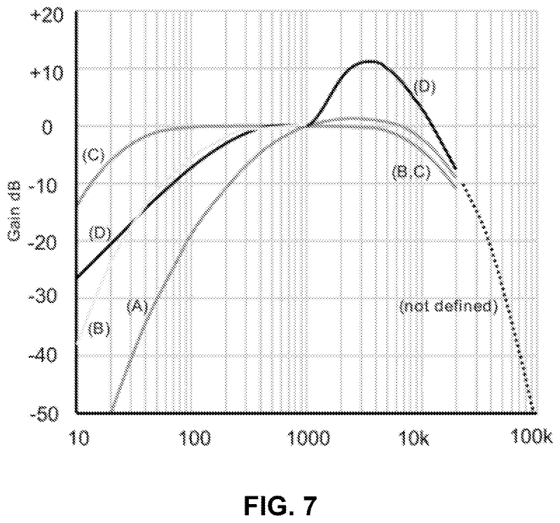

Conversion of Wₜₒₜ as a power into acoustic decibels, dBA, proceeds as usual, using the human acoustic-response curve to cover power-decibels into dBA, i.e., human-weighted decibels of power (curve A in FIG. 7). The raw power curve is the acoustic spectrum measured by the laser vibrometer, which is stored and processed through these dB calculations.

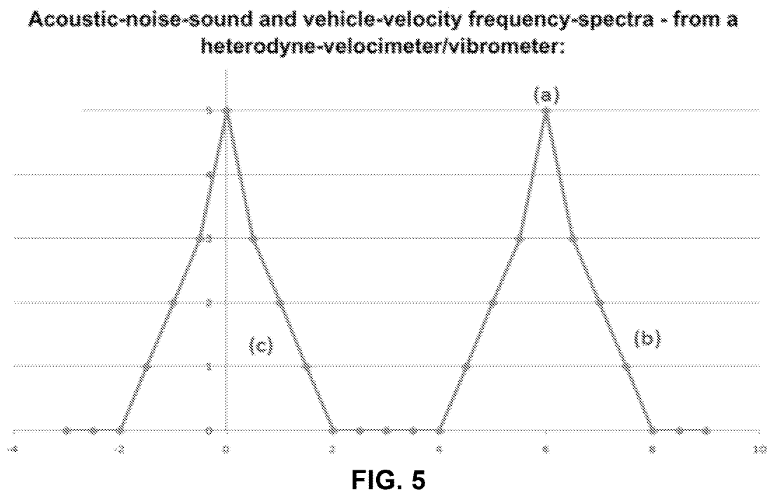

FIG. 5—shown schematically, frequency/velocity-spectra of the (a) (narrow) object or surface velocity-component—and (b) (broad) noise-sound across audio-frequencies and beyond, as might be measured. The horizontal axis represents frequency (arbitrary numbers here), the vertical axis represents amplitude or intensity of that frequency. It is possible for the object or surface's velocity to bias the object or surface's noise-spectrum frequencies (the Doppler-shift), so it is necessary then to add-or-subtract the object or surface frequency at (a)—from curves (a) and (b)—thus to place the noise-sound frequencies of (b) in their correct location at (c)—to get the correct acoustic-noise frequencies required for power/dBA calculations described above.

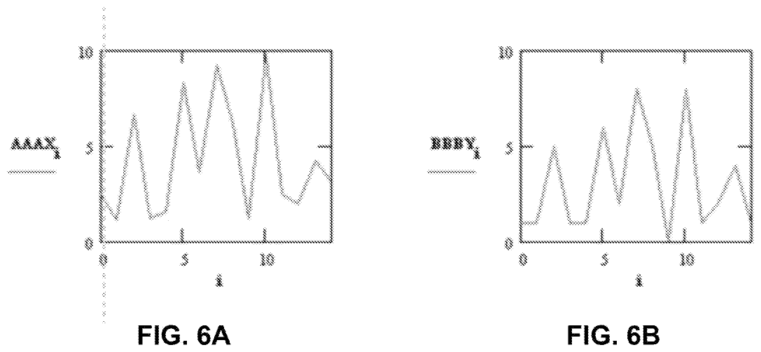

FIGS. 6A-6B offer an optional additional procedure to corroborate the measurement from the radar/laser-vibrometer inside the police lidar/radar. The present invention measures the noise-sound-spectrum and intensity-level as heard by an acoustically calibrated directional-microphone placed on the laser-radar instrument, ie, as heard by the police officer—the present invention cross-correlates the acoustic spectrum at the observer with the laser-radar's sound spectrum at the object or surface. This may assist in cross-verification of the lidar/radar's measurement of sound-intensity from the specific object or surface that is photographed to provide additional evidence of the sound-measurements.

Cross-correlation of two mm-element spectra, xi and yi, proceeds by the following standard statistical mathematics to achieve the correlation coefficient rxy.

$$xi := {\sum }_{n - 0}^{m m} A {X}_{n} yi := {\sum }_{n = 0}^{m m} B {Y}_{n}$$

$$xiyi := {\sum }_{n = 0}^{m m} A {X}_{n} \cdot {BY}_{n} x 2 i := {\sum }_{n = 0}^{m m} {( A {X}_{n} )}^{2} y 2 i := {\sum }_{n = 0}^{m m} {( B {Y}_{n} )}^{2} rxy := \frac{( m m + 1 ) \cdot xiyi - xi \cdot vi}{{[ ( m m + 1 ) \cdot x 2 i - {xi}^{2} ]}^{0.5} \cdot {[ ( m m + 1 ) \cdot y 2 i - y {i}^{2} ]}^{0.5}} \qquad ( 3 )$$

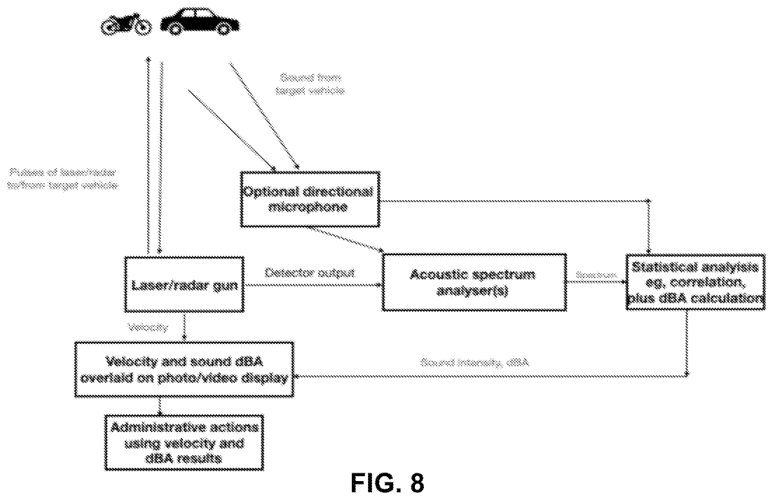

The left-hand spectrum in FIG. 6A is a simulated noisy directional-microphone (graph AAAX), the right-hand spectra is a simulated low-noise lidar/radar-spectrum of the same sound (graph BBBY). The correlation-coefficient in this example is 97%, with a 95% confidence-level that the spectrum-correlation is between 92% and 99%. Implementation of the present invention may involve additional hardware to go inside the police camera (for example, a “Raspberry Pi”-type computer-card and perhaps one (or two) acoustic spectrum analyser chips—the total size and weight of a credit card—with negligible extra power consumption, so the lidar/radar camera can be used and re-charged daily, as usual. This hardware may be retro-fitable to existing police lidars/radars). Implementation of the present invention may involve a software implementation, where the techniques are either incorporated into newly-manufactured equipment or, ideally, distributed to existing equipment as a software upgrade. Whilst the present invention may have implied LIDAR and RADAR ‘guns’, a cell-phone or mobile-phone fitted with LIDAR and a camera—could also be used to measure and record sound-intensity emitted by an object. An overall system schematic diagram is shown and explained in FIG. 8.

The equivalence of the Spectrum and the Fourier Transform of the spectrum, the auto-correlation function—is well understood and widely used in signal processing. This is known as the Wiener-Khinchin Theorem—which states that the autocorrelation function of a wide-sense-stationary random process has a spectral decomposition given by the power spectrum of that process. Calculation of the spectrum or the auto-correlation function of the detector's signal contains the same information, and are interchangeable. Being interchangeable such processes are therefore selectable—depending on the relative ease and cost of their technological implementation. Thus, in the present application, the use of the term spectrum analysis/analyzer could be interpreted as ‘spectrum of auto-correlation function’. This may suggest alternative signal processing involving auto-correlation and Fast Fourier Transform (FFT).

Estimation of the laser/radar beam area, S, at the known distance of the target (from the pulse round-trip time) is simple geometry using the beam-divergence and range. The characteristic dimension, R, of the object or surface is easily measured from its size in the image, by geometry or maybe using AI. All other parameters in the equations are trivially measured or estimated, except “v-squared bar”, the surface velocity fluctuations. To measure “v-squared bar” with a laser-based system using only pulse round-trip times, the present invention estimates small changes of the pulse-width. This is traditionally done by pulse-auto-correlation or more sophisticated techniques such as (acronyms) frequency-resolved optical gating (FROG) or spectral-phase interferometry for direct electric-field reconstruction (SPIDER). These lab techniques may be made in an optical-integrated-circuit or photonic-integrated-chip (PIC), but that's likely expensive. If the surface-vibrations are large enough, and the object or surface velocity is essentially constant during the measurement-time, then v-squared-bar may be estimated from the variance of the (velocity-corrected) distribution of round-trip times, in the same manner as shown in FIG. 5, and described below.

However, the heterodyne-radar, and possible heterodyne-laser-based systems may measure changes to the oscillation carrier-frequency of the original radar/laser pulse, not its pulse-length. Frequency-changes may be estimated from the proposed use in the present application of an acoustic spectrum analyser working on the detector output. The spectrum-peak relates directly to the target velocity, and the variance of the spectral-shape relates directly to “v-squared bar”, exactly as required for the noise-calculations set out here. Only simple, standard peak-position & statistical variance calculations are needed, for velocity, and to estimate “v-squared bar”. [In statistics, variance is standard-deviation (i.e., ‘root mean square’) squared, therefore equal to the mean-square value, as required to estimate v-squared-bar. The “bar” (or average) value is natural—as the integration (or averaging) over the velocity (=frequency) distribution (=spectrum) is used to calculate the rms and variance values; errors are very small with respect to dBA's logarithmic calculations].

In an exemplary scenario, a 5-centimeter diameter exhaust-pipe of a motor-bike is measured as part of a 1-meter diameter laser-radar spot incident upon it whilst (stationary or) moving. The dominant frequency measured in the acoustic spectrum being emitted by that motor-bike is ˜1-KHz on a warm day at ˜20 degrees Centigrade, so the velocity of the sound is ˜343 meters-per-second, and the air-density is ˜1.225 kg per cubic meter. The distribution of velocities measured in the LIDAR's velocity-distribution is assumed for the example calculation here—to give v-squared-bar ˜0.5, so the emitted sound-power calculates to Wₜₒₜ˜139 Watts, which, at the ˜1-KHz frequency is ˜141 dB, i.e., ˜116 dBA when acoustically-weighted for the ˜1-KHz sound-frequency.

Note that the present invention is capable of detecting the noise from a single object or surface which may be any vibrating surface that creates noise, for non-limiting illustration a car, motor-bike, truck, boat, jet-ski, aircraft or drone. These noise sources can be detected in environments where the said source is the only primary source of noise, as well as in environments where many other noise sources are present. In the latter case, a single source of noise is able to be picked out from other sources for identification and/or localization.

In some embodiments, a pulsed laser is implemented at the instant of measurement of the source's noise level. An output of the pulsed laser allows for a precise range of that noise source, a parameter required for the subsequent computation of the noise level at that instant. By measuring the round-trip time of the laser-pulse from the radar/lidar set being used, because light travels approximately 1-foot per nano-second, a nano-second wide pulse yields a range accuracy of approximately 1-2 feet more than accurate enough for accurate noise-level estimate calculations to be reliable for ranges of 50 feet or more.

Instructions that cause at least one processing circuit to perform one or more operations are “computer-executable.” Within the scope of the present invention, “computer-readable memory,” “memory component,” and the like comprises two distinctly different kinds of computer-readable media: physical storage media that stores computer-executable instructions and transmission media that carries computer-executable instructions. Physical storage media includes RAM and other volatile types of memory; ROM, EEPROM and other non-volatile types of memory; CD-ROM, CD-RW, DVD-ROM, DVD-RW, and other optical disk storage; magnetic disk storage or other magnetic storage devices; and any other tangible medium that can store computer-executable instructions that can be accessed and processed by at least one processing circuit. Transmission media can include signals carrying computer-executable instructions over a network to be received by a general-purpose or special-purpose computer. Thus, it is emphasized that (by disclosure or recitation of the exemplary term “non-transitory”) embodiments of the present invention expressly exclude signals carrying computer-executable instructions. However, it should be understood that once a signal carrying computer-executable instructions is received by a computer, the type of computer-readable storage media transforms automatically from transmission media to physical storage media. This transformation may even occur early on in intermediate memory such as (by way of example and not limitation) a buffer in the RAM of a network interface card, regardless of whether the buffer's content is later transferred to less volatile RAM in the computer.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting essentially of” or “consisting of”, and as such the written description requirement for claiming one or more embodiments of the present invention using the phrase “consisting essentially of” or “consisting of” is met.

The reference numbers recited in the below claims are solely for ease of examination of this patent application, and are exemplary, and are not intended in any way to limit the scope of the claims to the particular features having the corresponding reference numbers in the drawings.

1. A method for measuring noise of a single object or surface in a soundscape of multiple noise-emitting objects or surfaces, the method comprising:
a. providing a heterodyne signal system (200) comprising:
i. a signal emitter (210);
ii. a signal receiver (220); and
iii. a signal processing component (230);
b. directing, by the signal emitter (210), an original signal to the single object or surface;
c. accepting, by the signal receiver (220), a return signal, wherein the return signal is Doppler shifted and mixed with the original signal;
d. removing, by the signal processing component (230), the original signal, resulting in an output signal comprising changes to oscillation carrier frequency;
e. calculating, by an acoustic spectrum analyzer (300) communicatively coupled to the heterodyne signal system (200), a radiation-factor from the output signal;
f. calculating, by the acoustic spectrum analyzer (300), a mean-squared velocity value from the output signal, wherein calculating the mean-squared velocity value comprises calculating a variance of a spectral shape of the output signal;
g. calculating, by the acoustic spectrum analyzer (300), a noise-sound-power value from the mean-squared velocity value and the radiation-factor; and
h. converting, by the acoustic spectrum analyzer (300), the noise-sound-power value into an acoustic decibel value.

2. The method of claim 1, wherein the heterodyne signal system (200) comprises a LIDAR signal system.

3. The method of claim 1, wherein the heterodyne signal system (200) comprises a laser signal system or a RADAR signal system.

4. The method of claim 1, wherein the heterodyne signal system (200) further comprises a laser/RADAR gun.

5. The method of claim 1, wherein the heterodyne signal system (200) and the acoustic spectrum analyzer (300) comprise a portable computing device.

6. The method of claim 1 further comprising providing a calibrated directional microphone placed on or near the heterodyne signal system (200) for cross-checking noise-intensity level and spectrum calculated by the acoustic spectrum analyzer (300).

7. The method of claim 1 further comprising employing machine vision, artificial intelligence, or a combination thereof for calculation of sound-source dimensions.

8. The method of claim 1 further comprising recording, by a camera, a photograph or video recording of the single object or surface.

9. The method of claim 1, wherein the single target object or surface is a vibrating surface that creates noise.

10. The method of claim 1 further comprising steps for:
a. actuating, upon accepting the return signal, a pulsed laser to generate a laser-pulse;
b. measuring, by the heterodyne signal system (200), a round-trip time of the laser-pulse; and
c. calculating a range of the single object or surface based on the round-trip time of the laser-pulse.

11. A system (100) for measuring noise of a single object or surface in a soundscape of multiple noise-emitting objects or surfaces, the system comprising:
a. a heterodyne signal system (200) comprising:
i. a signal emitter (210);
ii. a signal receiver (220); and
iii. a signal processing component (230) capable of executing computer readable instructions comprising:
1. directing an original signal to the single object or surface;
2. accepting a return signal, wherein the return signal is Doppler shifted and mixed with the original signal; and
3. removing the original signal, resulting in an output signal comprising changes to oscillation carrier frequency; and
b. an acoustic spectrum analyzer (300) communicatively coupled to the heterodyne signal system (200) capable of executing computer-readable instructions comprising:
i. accepting the output signal from the heterodyne signal system (200);
ii. calculating a radiation-factor from the output signal;
iii. calculating a mean-squared velocity value from the output signal, wherein calculating the mean-squared velocity value comprises calculating a variance of a spectral shape of the output signal;
iv. calculating a noise-sound-power value from the mean-squared velocity value and the radiation-factor; and
v. converting the noise-sound-power value into an acoustic decibel value.

12. The system (100) of claim 11, wherein the heterodyne signal system (200) comprises a LIDAR signal system.

13. The system (100) of claim 11, wherein the heterodyne signal system (200) comprises a laser signal system or a RADAR signal system.

14. The system (100) of claim 11, wherein the heterodyne signal system (200) further comprises a laser/RADAR gun.

15. The system (100) of claim 11, wherein the heterodyne signal system (200) and the acoustic spectrum analyzer (300) comprise a portable computing device.

16. The system (100) of claim 11 further comprising a calibrated directional microphone placed on or near the heterodyne signal system (200) for cross-checking noise-intensity level and spectrum calculated by the acoustic spectrum analyzer (300).

17. The system (100) of claim 11 further comprising a machine learning component for employing machine vision, artificial intelligence, or a combination thereof for calculation of sound-source dimensions.

18. The system (100) of claim 11 further comprising a camera for recording a photograph or video recording of the single object or surface.

19. The system (100) of claim 11, wherein the single target object or surface is a vibrating surface that creates noise.

20. The system (100) of claim 11 further comprising steps for:
a. actuating, upon accepting the return signal, a pulsed laser to generate a laser-pulse;
b. measuring, by the heterodyne signal system (200), a round-trip time of the laser-pulse; and
c. calculating a range of the single object or surface based on the round-trip time of the laser-pulse.
